(19) United States
(12) Patent Application Publication
(10) Pub. No.: US 2025/0015222 A1
(43) Pub. Date: Jan. 9, 2025

(54) Method for Making Single-Photon Detector, Single-Photon Detector Thereof, and Single-Photon Array Thereof

(71) Applicant: QUANZHOU SANAN OPTICAL COMMUNICATION TECHNOLOGY CO., LTD., Nan'an City Quanzhou, Fujian (CN)

(72) Inventors: Weizhong SUN, Nan'an City Quanzhou, Fujian (CN); Yanli ZHAO, Nan'an City Quanzhou, Fujian (CN); Zhengfeng CHEN, Nan'an City Quanzhou, Fujian (CN); Siyuan LIU, Nan'an City Quanzhou, Fujian (CN); Chao LIU, Nan'an City Quanzhou, Fujian (CN); Shuying QIU, Nan'an City Quanzhou, Fujian (CN); Jiuguo SUN, Nan'an City Quanzhou, Fujian (CN); Wenxin CHEN, Nan'an City Quanzhou, Fujian (CN)

(21) Appl. No.: 18/398,079

(22) Filed: Dec. 27, 2023

Related U.S. Application Data
(63) Continuation-in-part of application No. PCT/CN2022/118649, filed on Sep. 14, 2022.

(30) Foreign Application Priority Data
Sep. 30, 2021 (CN) 202111159738.9

(51) Int. Cl. H01L 31/18; H01L 25/04; H01L 31/0216; H01L 31/0304; H01L 31/107

(52) U.S. Cl. CPC H01L 31/184; H01L 25/042; H01L 31/0216; H01L 31/0304; H01L 31/107; H01L 31/1868

(57) ABSTRACT

A method of making a single-photon detector includes growing an epitaxial multi-layer structure that includes a buffer layer, an absorption layer, a transition layer, a field control charge layer, a multiplication layer, an inversion layer, a migration layer, a window layer, and an Ohmic contact layer sequentially on a substrate. A curved diffusion region is formed in the window layer and the Ohmic contact layer via a diffusion process. A mesa structure is formed by etching the epitaxial multi-layer. A light input window is formed on the substrate. A p-type electrode is formed on the Ohmic contact layer, and an n-type electrode is formed on the substrate. The inversion layer provides supplementary regulation of an electric field distribution that is regulated by the field control charge layer. A single-photon detector made from the method, and a single-photon detector array made with a multitude of the single-photon detectors are also provided.

### CROSS-REFERENCE TO RELATED APPLICATION

This application is a continuation-in-part (CIP) of International Application No. PCT/CN2022/118649, filed on Sep. 14, 2022, which claims priority to Chinese Invention patent application No. 202111159738.9, filed on Sep. 30, 2021.

### FIELD

The disclosure relates to a single-photon detector, and more particularly to a method for making a single-photon detector, a single-photon detector thus made, and a single-photon detector array formed from multiple single-photon detectors.

### BACKGROUND

Light is composed of photons which are the smallest unit of electromagnetic radiation. A single photon in the visible or near infra red range of the electromagnetic spectrum has approximately 10-19 joules of energy, and cannot be effectively detected with conventional photodetectors. However, single-photon detectors have been developed which have advantages such as high sensitivity, high signal to noise ratio, and low timing jitter, and which have been applied in quantum key distribution, lidars, fluorescence lifetime microscopy, and flow cytometers.

There are currently several types of single-photon detectors such as photomultiplier tubes (PMT), superconducting nanowire single-photon detectors (SNSPD), and single photon avalanche diodes (SPAD) etc. Photomultiplier tubes (PMT) use the photoelectric effect and secondary emission to reach gains of 104-108 times an input signal, and has high sensitivity which allows the PMT to be used for single-photon detection. However, PMTs have disadvantages such as low response to radiation above 1200 nm of the electromagnetic spectrum, relatively larger size, and larger dark count, and cannot completely satisfy the demands required of current photodetectors. SNSPDs, on the other hand, operates with the principle of superconducting phase transition, and has the advantage of both high sensitivity and low noise, and has better detection efficiency. However, SNSPDs require superconducting temperatures to operate and are unsuitable for application to general and daily use. SPADs operates via impact ionization which causes an avalanche current to develop. In terms of practicality, SPADs functions in the visible and near infra red range of the electromagnetic spectrum, has advantages such as high gain, low noise to gain ratio, low power consumption, and small size, and is currently the most widely utilized single-photon detector type having the most future potential. However, when SPADs operate under Geiger mode where the SPAD is operated above its breakdown threshold voltage, premature edge breakdown may occur.

There are currently two different conventional methods used to make a conventional single-photon detector of the SPAD type. FIG. 1, shows a conventional single-photon detector made with a first conventional method where a substrate 101 is provided and a buffer layer 102, an absorption layer 103, a transition layer 104, a field control charge layer 105, a multiplication layer 106 and an intrinsic layer 107 are sequentially formed above the substrate 101. Subsequently, two diffusion processes are performed to form a diffusion region 108 in the intrinsic layer 107, the multiplication layer 106, and the field control layer 105. An electric field distribution diagram of the conventional single-photon detector made from the first method is shown in FIG. 2. Referring to FIG. 2, the electric field is strongest at the multiplication layer 106 and is relatively weaker at the absorption layer 103 which ensures that impact ionization occurs in the multiplication layer 106 and not in the absorption layer 103. This helps to guarantee that charge carriers are migrating at the saturation velocity and increases the response speed of the conventional single-photon detector. The first conventional method makes a conventional single-photon detector that effectively mitigates premature edge breakdown; however, the first conventional method requires performing two diffusion processes which are difficult to control and may result in low yield. Additionally, large single-photon detector arrays are harder to form with conventional single-photon detectors made via the first conventional method.

FIG. 3 shows a conventional single-photon detector made with a second conventional method. The second conventional method includes providing a substrate 101 and performing a first epitaxial growth to form a buffer layer 102, an absorption layer 103, a transition layer 104, a field control charge layer 105, a multiplication layer 106, and an intrinsic layer 107. Next, a diffusion process is used to form a diffusion region 108 in the intrinsic layer 107 and the multiplication layer 106. Subsequently, the field control charge layer 105 is etched to form a mesa, and an indium phosphide (InP) layer 109 is formed on the etched mesa via a secondary epitaxial growth. A conventional single-photon detector made with the second conventional method effectively mitigates premature edge breakdown; however, the second conventional method requires using a first epitaxial growth followed by a diffusion process, and etching the absorption layer 103 followed by the secondary epitaxial growth. An interface formed during the two-stage epitaxial growth is very difficult control under a high electric field. Therefore, the second conventional method is difficult to perform and has low yield.

### SUMMARY

Therefore, an object of the disclosure is to provide a method of making a single-photon detector that can alleviate at least one of the drawbacks of the prior art.

According to a first aspect of the disclosure, the method of making a single-photon detector includes: a) growing an epitaxial multi-layer structure on a top side of a substrate, the epitaxial multi-layer structure including a buffer layer, an absorption layer, a transition layer, a field control charge layer, a multiplication layer, an inversion layer, a migration layer, a window layer, and an Ohmic contact layer that are sequentially stacked from bottom up in that order; b) forming a curved diffusion region in the window layer and the Ohmic contact layer via a diffusion process; c) forming a mesa structure by etching an outer periphery of the epitaxial multi-layer structure on the substrate; d) forming a light input window on a bottom side of the substrate that is adapted for inletting light; e) forming a p-type electrode on the Ohmic contact layer, and an n-type electrode on the bottom side of the substrate, wherein the inversion layer provides supplementary regulation of an electric field distribution that is regulated by the field control charge layer.

According to second aspect of the disclosure, a single-photon detector includes a substrate, an epitaxial multi-layer structure, a curved diffusion region, a mesa structure, a light input window, a p-type electrode, and an n-type electrode. The epitaxial multi-layer structure includes a buffer layer, an absorption layer, a transition layer, a field control charge layer, a multiplication layer, an inversion layer, a migration layer, a window layer, and an Ohmic contact layer that are sequentially stacked from bottom up in that order on a top side of the substrate. The curved diffusion region is formed in the Ohmic contact layer and the window layer. The mesa structure is formed via etching on a portion of an outer periphery of the epitaxial multi-layer structure. The light input window is formed on a bottom side of the substrate adapted for inletting light. The p-type electrode formed on the Ohmic contact layer. The n-type electrode is formed on the bottom side of the substrate. The inversion layer provides supplementary regulation of an electric field distribution that is regulated by the field control charge layer.

According to a final aspect of the disclosure, the single-photon detector array includes a plurality of single-photon detectors as described in the second aspect that are arranged in an array via a flip chip connection and integrated into an addressable circuit. The p-type electrodes of the single-photon detectors are electrically isolated from each other and the n-type electrodes of the single-photon detectors are electrically connected to form a common electrode.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating a conventional single-photon diode.

FIG. 2 is a graph illustrating an electric field distribution of a conventional single-photon diode.

FIG. 3 is a schematic view illustrating another conventional single-photon diode.

FIG. 4 is a block diagram illustrating an embodiment of a method of making a single-photon diode according to the present disclosure

FIGS. 5 to 10 illustrate the single-photon diode in steps S110 to S150 of the method, respectively.

FIG. 11 is a graph of an electric field distribution of an embodiment of a single-photon diode according to the present disclosure.

FIG. 12 is a schematic view illustrating an embodiment of a single-photon diode array according to the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

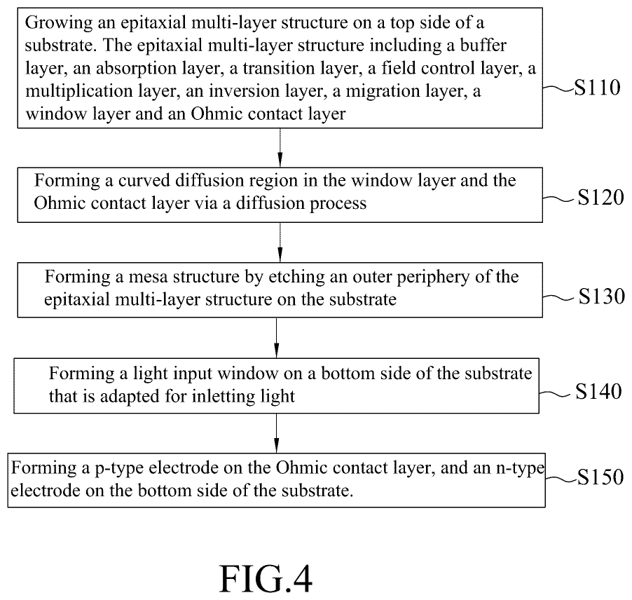

Referring to FIG. 4, an embodiment of a method of making a single-photon detector according to the present disclosure includes steps S110-S150.

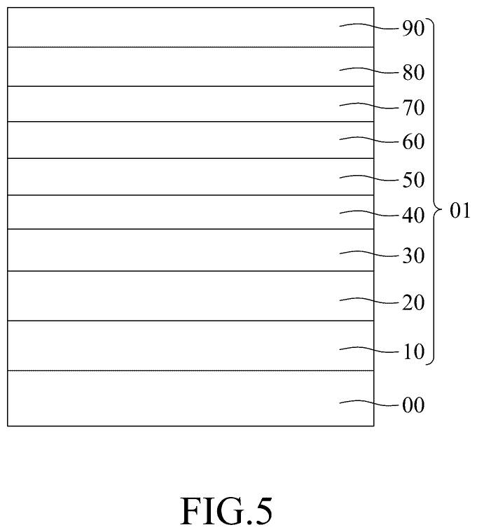

Referring to FIGS. 5 to 10, the step S110 includes growing an epitaxial multi-layer structure 01 on a top side of a substrate 00. The epitaxial multi-layer structure 01 includes a buffer layer 10, an absorption layer 20, a transition layer 30, a field control charge layer 40, a multiplication layer 50, an inversion layer 60, a migration layer 70, a window layer 80, and an Ohmic contact layer 90 that are sequentially stacked from bottom up in that order.

The subsequent step S120 includes forming a curved diffusion region 901 in the window layer 80 and the Ohmic contact layer 90 via a diffusion process.

The subsequent step S130 includes forming a mesa structure by etching an outer periphery of the epitaxial multi-layer structure 01 on the substrate 00.

Furthermore, the step S140 includes forming a light input window 92 on a bottom side of the substrate 00 that is adapted for inletting light.

Subsequently, the step S150 includes forming a p-type electrode 93 on the Ohmic contact layer 90, and an n-type electrode 94 on the bottom side of the substrate 00. It should be noted that the n-type electrode 94 in the step S150 does not cover the light input window 92 formed in the step S140.

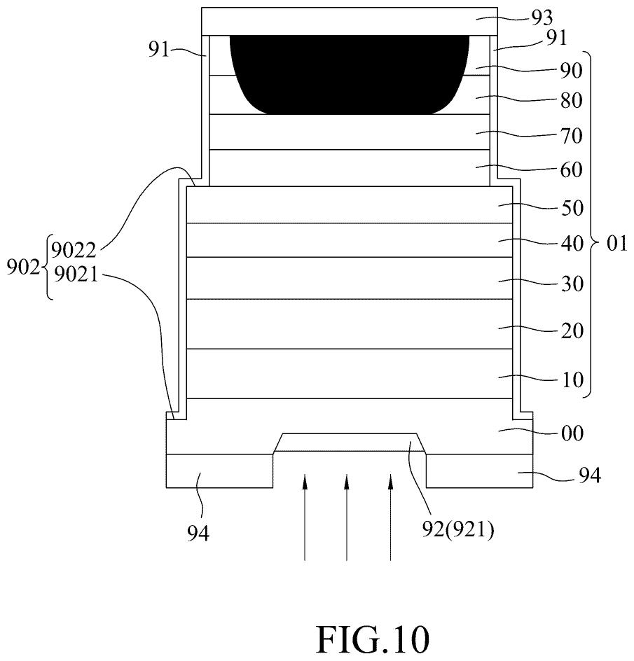

In this embodiment, during the step 110 of growing the epitaxial structure 01, the inversion layer 50 is introduced by epitaxial growth. The inversion layer 60 of the epitaxial multi-layer structure 01 provides supplementary regulation of an electric field distribution that is regulated by the field control charge layer 40. A single-photon detector of the disclosure made according to the embodiment of the method is shown in FIG. 10.

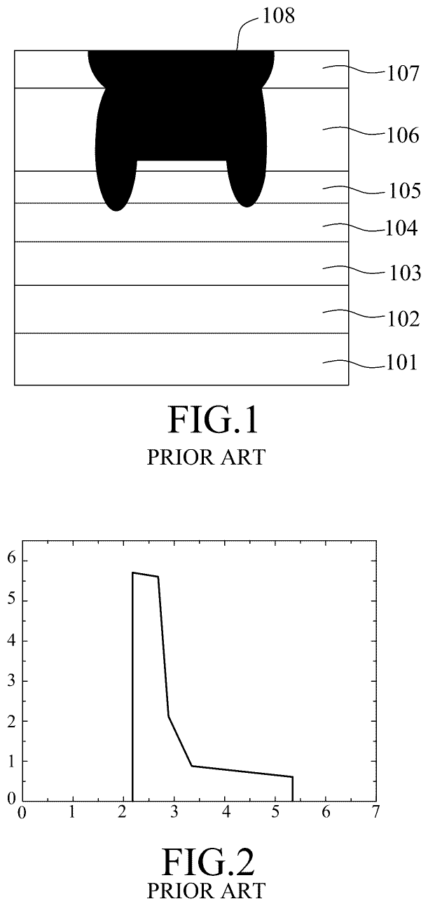

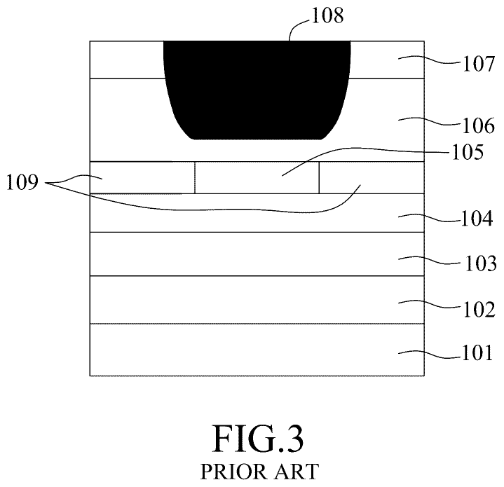

In this embodiment of the method of making the single-photon detector, only one diffusion process and only one epitaxial growth process are performed, and the inversion layer 60 is grown over the multiplication layer 50 to effectively mitigate premature edge breakdown. This method allows the single-photon detector to be made without performing a two-stage epitaxial growth process. Compared to the prior art shown in FIG. 1 in which two stage diffusion process is performed and the prior art shown in FIG. 3 in which a single stage diffusion process is followed by an etching step to perform the subsequent secondary epitaxial growth, the method of this embodiment reduces the complexity of fabricating single-photon detectors, increases the product yield, and is especially conducive for forming the single-photon detectors thus fabricated into a single-photon detector array.

Referring to FIG. 5, in this embodiment, the multi-layer structure 01 that includes the buffer layer 10, the absorption layer 20, the transition layer 30, the field control charge layer 40, the multiplication layer 50, the inversion layer 60, the migration layer 70, the window layer 80, and the Ohmic contact layer 90 may be formed sequentially in the described order in one epitaxial growth process.

The inversion layer 60 is made of one of InP, InGaAs, InAlAs, InAlGaAs, and InGaAsP, or any combination or combinations of the above. The inversion layer 60 may be made of a p-type doped layer such as InAlAs. More specifically, in some embodiments, the inversion layer 60 may be made of In_{0.52}Al_{0.48}As. The inversion layer 60 has an integral charge density that ranges from 2.0×e¹²/cm² to 4.0×e¹²/cm². In some embodiments, the inversion layer 60 has an integral charge density of 3.2×e¹²/cm². The inversion layer 60 may have a thickness that ranges from 150 nm to 300 nm which is conducive to regulating the electric field distribution and mitigating premature edge breakdown.

In this embodiment, the substrate 00 may be made of a highly doped n-type InP material. An n-type buffer layer 10 may be formed on the substrate via metal-organic chemical vapor deposition (MOCVD). A lattice constant of the buffer layer 10 should be close to the lattice constant of the substrate 00. For example, the buffer layer 10 may be an InP layer that has a thickness that ranges from 50 nm to 2000 nm. The buffer layer 10 may have an n-type doping concentration that ranges from 1×e¹⁵/cm³ to 1×e¹⁹/cm³.

In some embodiments, the buffer layer 10 may have a thickness of 1000 nm, and a doping concentration of 1×e¹⁸/cm³.

In this embodiment, the absorption layer 20 that is located above the buffer layer 10 is made of an n-type InGaAs material, and has a thickness that ranges from 2000 nm to 2800 nm. For example, the thickness of the absorption layer 20 may be 2000 nm, and the absorption layer 20 may be an intrinsic semiconductor doped with an n-type dopant. The transition layer 30 may be an intrinsic layer that has three transition sections, and may be made of an InGaAsP material with a thickness that ranges from 10 nm to 300 nm. In this embodiment, the transition layer 30 may effectively increase the response speed of the single-photon detector.

The field control charge layer 40 may have a thickness that ranges from 150 nm to 300 nm. The field control charge layer 40 may be made of an n-type InP material having an integral charge density that ranges from 2.4×e¹²/cm² to 4.8×e¹²/cm². In some embodiments, the field control charge layer 40 has an integral charge density of 2.4×e¹²/cm². The field control charge layer 40 regulates the electric field distribution, and mitigates premature edge breakdown.

The multiplication layer 50 is where impact ionization occurs in the single-photon detector between charge carriers and crystal lattice. The multiplication layer 50 may be made of a material such as InP, AlGaAsSb, or SiC that are used for generating impact ionization in avalanche photo diodes. These materials are characterized by having a hole impact ionization coefficient that is higher than their electron ionization coefficient.

The multiplication layer 50 has a thickness that ranges from 400 nm to 800 nm. In some embodiments, the multiplication layer 50 is made of an intrinsic InP material and has a thickness of 500 nm.

The migration layer 70 is made of one of InP, InGaAs, InAlAs, InAlGaAs, and InGaAsP, or any combination or combinations of the above. However, the migration layer 70 is not limited to the above materials. The migration layer 70 has a thickness that ranges from 500 nm to 700 nm. In some embodiments, the migration layer 70 may have a thickness of 500 nm. The migration layer 70 may be made of an intrinsic n-type semiconductor material, or lightly doped with an n-type dopant. The n-type doping concentration of the migration layer may range from 1×e¹⁵/cm³ to 1×e¹⁷/cm³.

The window layer 80 and the Ohmic contact layer 90 may be formed in a single diffusion process with a diffusion concentration that ranges from 1×e¹⁷/cm³ to 5×e¹⁹/cm³. In other embodiments, the window layer 80 and the Ohmic contact layer 90 may be formed via MOCVD. The window layer 80 may have a thickness that ranges from 1000 nm to 1500 nm. The Ohmic contact layer 90 may have a thickness that ranges from 100 nm to 200 nm. In some embodiments, the Ohmic contact layer may have a thickness of 100 nm. The Ohmic contact layer 90 is primarily used for forming an Ohmic contact with a P-type electrode the higher the doping concentration of the Ohmic contact layer 90, the better the Ohmic contact. Therefore, the thickness of the Ohmic contact layer 80 is not necessarily of primary concern; however, the thickness of the Ohmic contact layer 80 should not be overly thick, otherwise the rate of the p-type diffusion process to form the curved diffusion region 901 will be affected.

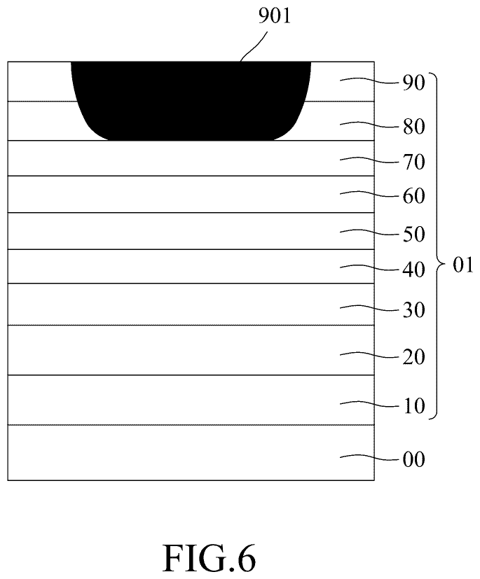

Referring to FIG. 6 in combination with FIG. 4, in this embodiment, the step S120 of forming the curved diffusion region 901 in the window layer 80 and the Ohmic contact layer 90 may include forming a preparatory etch layer (not shown) on the Ohmic contact layer 90. Subsequently, an etching region (not shown) is defined on the preparatory etch layer, and the etching region is then etched away from the preparatory etch layer to form an etched opening (not shown) that corresponds to the etching region and that exposes a portion of the Ohmic contact layer 90. Next, the curved diffusion region 901 is formed via a p-type diffusion process that is performed on the Ohmic contact layer 90 and the window layer 80 through the etched opening with a p-type dopant.

In this embodiment, the preparatory etch layer may be formed on the Ohmic contact layer 90 via plasma enhanced chemical vapor deposition (PECVD). The preparatory etch layer may be a silicon dioxide (SiO₂) or silicon nitride (SiNx) thin-film, and may have a thickness of 400 nm.

The etching region may be defined as a central region of the preparatory etch layer, for example, a circular region at the centre of the preparatory etch layer. The etching region may be etched away from the preparatory etch layer via grayscale lithography and other etching techniques to form the etched opening that passes through the preparatory etch layer and exposes a portion of the Ohmic contact layer 90.

The Ohmic contact layer 90 and the window layer 80 are then diffused with a p-type diffusion process through the etched opening to form the curved diffusion region 901.

After performing the diffusion process, the remaining preparatory etch layer may be peeled away and the single-photon detector may be cleaned and washed.

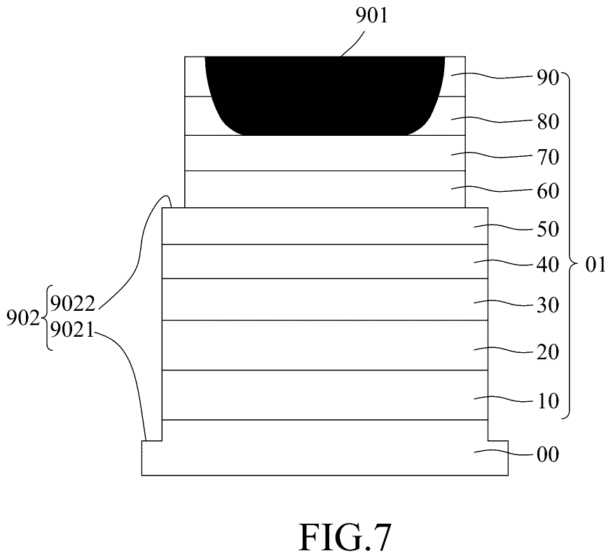

Referring to FIG. 7 in combination with FIG. 4, In this in embodiment, the mesa structure has a first mesa 9021 on the substrate 00, and a second mesa 9022 on the multiplication layer 50. The step S130 of forming the mesa structure 902 includes etching an outer periphery of each of the Ohmic contact layer 90, the window layer 80, the migration layer 70, the inversion layer 60, the multiplication layer 50, the field control charge layer 40, the transition layer 30, the absorption layer 20, the buffer layer 10, and the substrate 00 until the substrate 00 is recessed to a depth below the top side of the substrate 00 so that the layers above the substrate 00 are formed into the first mesa 9021. The step 130 further includes further etching the outer periphery of each of the Ohmic contact layer 90, the window layer 80, the migration layer 70, and the inversion layer 60 until a top surface of the outer periphery of the multiplication layer 50 is exposed so that the layers above the multiplication layer 50 are formed into the second mesa 9022.

In this embodiment the outer periphery of each of the Ohmic contact layer 90, the window layer 80, the migration layer 70, the inversion layer 60, the multiplication layer 50, the field control charge layer 40, the transition layer 30, the absorption layer 20, the buffer layer 10, and the substrate 00 may be etched via a dry etching process, a wet etching process or a combination of both processes. In some embodiments, the window layer 80 is made of an InP material and a combined dry and wet etching process is used; in these cases, the Ohmic contact layer 90 may be etched with a sulfuric acid based etchant instead of a hydrochloric acid based etchant since hydrochloric acid will more easily etch into the InP material of the window layer 80 and make the etching process more difficult to control.

The first mesa 9021 is formed on the substrate 00 to create better separation between single-photon detectors when multiple single-photon detectors are formed into a single-photon detector array. The etch width of the etching process to form the first mesa 9021 may range from 1 μm to 100 μm, for example, the etch width is 5 μm. Therefore, a single-photon detector array formed from single-photon detectors according to the present disclosure will have a separation that ranges from 1 μm to 100 μm between adjacent single-photon detectors in the array.

Referring again to FIG. 7, the second mesa 9022 is formed by further etching the outer periphery of each of the Ohmic contact layer 90, the window layer 80, the migration layer 70, and the inversion layer 60 until a top in surface of the outer periphery of the multiplication layer 50 is exposed.

In this embodiment, the second mesa 9022 may be formed via a dry etching process, a wet etching process or a combination of both processes. The second mesa 9022 formed on the first mesa 9021 by etching various layers above the multiplication layer 50 provides a small size region for multiplication while still maintaining a large size region for light entry and absorption. This allows more photons to enter the single-photon detector for absorption but limit the area in which impact ionization may occur, thereby increasing detector efficiency, and reducing the dark count.

In this embodiment, the window layer 80 is made of an InP material and the combined dry and wet etching process is used. The Ohmic contact layer 90 is etched with a sulfuric acid based etchant instead of a hydrochloric acid based etchant since hydrochloric acid will more easily etch into the InP material of the window layer 80 and make the etching process more difficult to control which may hinder the formation of the second mesa 9022.

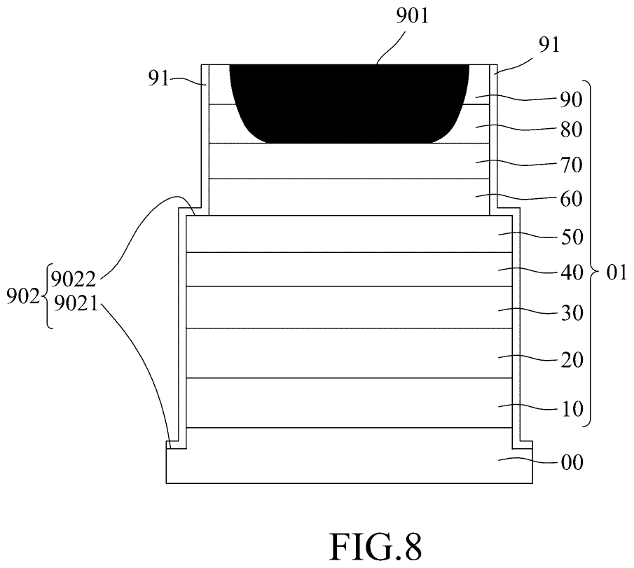

Referring to FIG. 8, the method for making the single-photon detector further includes forming a passivation layer 91 over the first mesa 9021, and the second mesa 9022. In this embodiment, the passivation layer 91 may be formed via PECVD over the first mesa 9021 and the second mesa 9022. The passivation layer 91 is made from a high resistivity polymer material, or one of SiO₂, SiNₓ, and Al₂O₃, or any combination or combinations of the above.

The passivation layer 91 may have a thickness that ranges from 5 nm to 3000 nm, and passivates the mesa structure 902. In some embodiments, the passivation layer 91 is a silicon nitride (SiNx) thin-film formed via PECVD with a thickness of 500 nm. In this embodiment, the passivation layer 91 passivates the mesa structure 902 and decreases the effects of dark current.

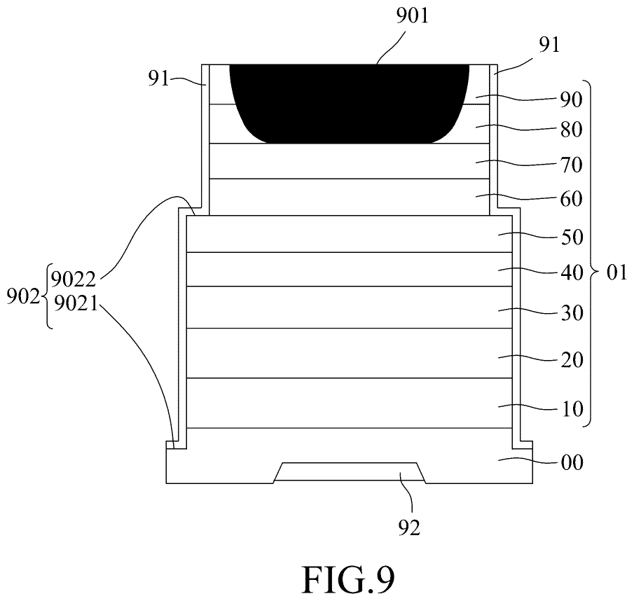

Referring to FIG. 9, in this embodiment, the step S140 is to form the light input window 92 which includes an anti-reflective coating 921. The step S140 of forming the light input window 92 includes etching the bottom side of the substrate 00 to form a recess with a depth from the bottom side being less than an entire thickness of the substrate 00, and filling the recess of the substrate 00 with the anti-reflective coating 921 to form the light input window 92.

In this embodiment, the anti-reflective coating 921 may be SiO₂, SiNₓ or other similar optical coatings. In some embodiment, the anti-reflective coating 921 is SiO₂ formed via PECVD with a thickness of 1600 nm. The light input window 92 that is formed from the anti-reflective coating 921 is adapted for inletting light. The single photon diode has an active area that is located in an upper region of the epitaxial multi-layer structure 01 and that is aligned with a light path of photons entering the light input window 92.

Referring to FIG. 10, in this embodiment, in the step S150 a p-type electrode 93 is formed above the epitaxial multi-layer structure 01 via electron-beam physical vapor deposition (EBPVD) or other similar deposition methods. The p-type electrode 93 may be made from titanium (Ti), platinum (Pt) or gold (Au). When multiple single-photon detectors are formed into a single-photon detector array, the p-type electrodes 93 of each single-photon detector are spaced apart and electrically isolated from each other. In this embodiment, the p-type electrode 93 covers the entire active area and may act as a metal reflection layer to reflect light entering from a substrate 00 side of the single-photon detector, thereby increasing detection efficiency.

In this embodiment, the substrate 00 may undergo planarization, and an n-type electrode 94 may be formed over a large area of the bottom side of the substrate 00 after planarization. When multiple single-photon detectors are formed into a single-photon detector array, the n-type electrode 94 of each of the single-photon detectors are electrically connected together to form a common n-type electrode 94 which is shared by all the individual single-photon detectors. This helps to ensure reliability and good Ohmic contact characteristics of the single-photon detectors.

Referring to FIG. 10, an embodiment of the single-photon detector made from the disclosed method includes a substrate 00, an epitaxial multi-layer structure 01, a curved diffusion region 901, a mesa structure 902, a light input window 92, a p-type electrode 93, and a n-type electrode 94. The epitaxial multi-layer structure 01 includes a buffer layer 10, an absorption layer 20, a transitional layer 30, a field control charge layer 40, a multiplication layer 50, an inversion layer 60, a migration layer 70, a window layer 80, and an Ohmic contact layer 90 that are sequentially stacked from bottom up in that order on a top side of the substrate 00. The curved diffusion region 901 is formed in the Ohmic contact layer 90 and the window layer 80. The mesa structure 902 is formed via etching on a portion of an outer periphery of the epitaxial multi-layer structure 01. The light input window 92 is formed on a bottom side of the substrate 00 and is adapted for inletting light. The p-type electrode 93 is formed on the Ohmic contact layer 90. The n-type electrode 94 is formed on the bottom side of the substrate 00. The substrate 00 has a recess indenting from the bottom side of the substrate 00. A depth of the recess is less than an entire thickness of the substrate 00. An anti-reflective coating 921 is filled in the recess of the substrate to form the light input window 92.

In this embodiment, the single-photon detector is a single photon avalanche diode (SPAD) that operates under reverse bias current, which means the p-type electrode 93 is connected to a lower electric potential while the n-type electrode 94 is connected to a higher electric potential. Photons of incident light enter from one side of the n-type electrode 94 and travel toward the p-type electrode 93 and are absorbed in the absorption layer 20, thereby creating electron hole pairs which then pass through the multiplication layer 50 which creates even more electron hole pairs through an avalanche effect. The absorption layer 20 has a larger difference in energy levels with the field control charge layer 40 than with the multiplication layer 50. Therefore the multiplication layer 50 may mitigate charge carrier mobility reduction due to discontinuous band gap between the field control charge layer 40 and the absorption layer 20. In this embodiment, by virtue of the inversion layer 60, the electric field in the migration layer 70 may be reduced, and ensure that an interface between the migration layer 70 and the window layer 80 operates under a lower electric field, thereby effectively preventing premature edge breakdown. The electric field distribution of the SPAD may be regulated by controlling the strength of the electric field in the field control charge layer 40 and the inversion layer 60 so that various layers of the SPAD can have a proper electric field when becoming exhausted during the operation of the SPAD, thereby ensuring high charge carrier drift velocity, and preventing the occurrence of detrimental avalanche effects caused by excessively high dark current created by a high electric field.

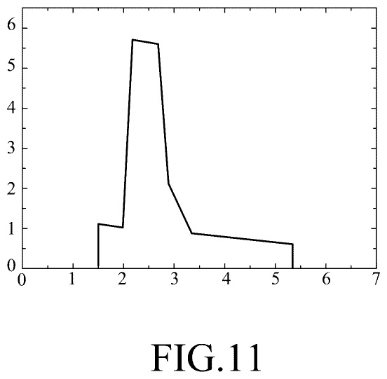

FIG. 11 shows an electric field distribution of the single-photon detector. It may be observed from FIG. 11 that the electric field at the multiplication layer 50 is greater than 5×105 V/cm, the electric field at the absorption layer 20 is less than 1×105 V/cm, and the electric field at the migration layer 70 is less than 1×105 V/cm.

In this embodiment, the epitaxial multi-layer structure 01 includes the inversion layer 60 that provides supplementary regulation of an electric field distribution that is regulated by the field control charge layer 40. The supplementary regulation provided by the inversion layer 60 may help to reduce the electric field at a periphery of the curved diffusion region 901, and effectively mitigate premature edge breakdown. Additionally, the single-photon detector in this embodiment can be obtained through a single state diffusion process and through epitaxial growth of the inversion layer 60. Two-stage epitaxial growth is not required to fabricate the single-photon detector. Therefore, the single-photon detector according to the present disclosure has advantages such as ease of manufacture, high reliability, and good yield.

The mesa structure 901 includes a first mesa 9021 and a second mesa 9022. The first mesa 9021 has a first mesa top defined by a top surface of the multiplication layer 50, and a first mesa sidewall extending downward to a peripheral surface of the substrate 00 lower than the top side of the substrate. The first mesa 9021 includes the multiplication layer 50, the field control charge layer 40, the transition layer 30, the absorption layer 20, the buffer layer 10, and a portion of the substrate 00. The second mesa 9022 has a second mesa top defined by a top surface of the Ohmic contact layer 90, and a second mesa sidewall that extends downward to the first mesa top. The second mesa 9022 includes the Ohmic contact layer 90, the window layer 80, the migration layer 70, and the inversion layer 60. In this embodiment, the passivation layer 91 is formed over the first and second mesa tops and sidewalls of the first mesa 9021 and the second mesa 9022.

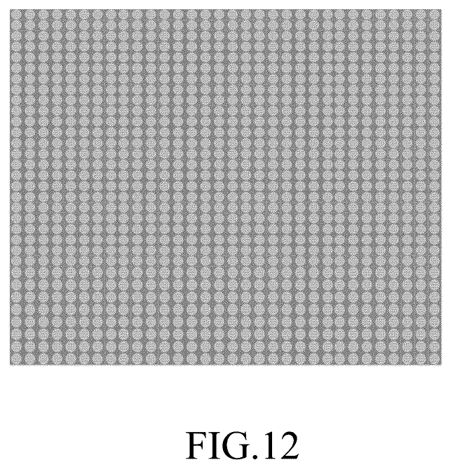

Referring to FIG. 12, a single-photon detector array includes a plurality of single-photon detectors made according to the method of the disclosure. The single-photon detectors of the single-photon detector array are arranged in an array via a flip-chip connection and integrated into an addressable circuit. More specifically, the single-photon detectors are flip-chip soldered and integrated onto a readout integrated circuit (ROIC). The p-type electrodes of the single-photon detectors are spaced apart and electrically isolated from each other, and the n-type electrodes of the single-photon detectors are electrically connected to form a common electrode.

In this embodiment, the single-photon detectors in the single-photon detector array are flip-chip soldered, the n-type electrode 94 is connected to a higher electric potential, and the p-type electrode 93 is connected to a lower electric potential. The single-photon detectors in the single-photon detector array are separated from each other by isolation trenches. The Isolation trenches are formed by the step of forming the first mesa 9021 (see FIG. 7) which removes various layers above the substrate 00 and part of the thickness of the substrate 00. The single-photon detector array is covered by the n-type electrode 94, is powered by the ROIC, and allows light to enter from the substrate side of each single-photon detector. Single photons detected by the single-photon detector array are converted into electric signals which are handled by a processor. The single-photon detector array is thus capable of detecting single photons.

The single-photon detector array has advantages such as a large photo sensitive area, and offering high multiplication while remaining compact in size, which allows the single-photon detector array to have high photon detection efficiency while lowering the dark count.

In summary of the above, in the method of making the single-photon detector, an epitaxial multi-layer structure 01 including a buffer layer 10, an absorption layer 20, a transition layer 30, a field control charge layer 40, a multiplication layer 50, an inversion layer 60, a migration layer 70, a window layer 80, and an Ohmic contact layer 90 are sequentially stacked from bottom up in that order on a top side of the substrate 00. A curved diffusion region 901 is formed in the window layer 80 and the Ohmic contact layer 90 via a diffusion process. A mesa structure 902 is formed by etching an outer periphery of the epitaxial multi-layer structure 01 on the substrate 00. A light input window 92 is formed on a bottom side of the substrate 00 that is adapted for inletting light. A p-type electrode 93 is formed on the Ohmic contact layer 90, and an n-type electrode 94 is formed on the bottom side of the substrate 00. The method of the present disclosure has the advantage of only requiring one diffusion process, and including the inversion layer 60. This effectively reduces the electric field at the periphery of the curved diffusion region 901, and effectively mitigates premature edge breakdown. Additionally, compared to conventional methods that require the application of two diffusion processes or two-stage epitaxial growth, the method of the present disclosure is easier to perform.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method of making a single-photon detector comprising:
growing an epitaxial multi-layer structure on a top side of a substrate, the epitaxial multi-layer structure including a buffer layer, an absorption layer, a transition layer, a field control charge layer, a multiplication layer, an inversion layer, a migration layer, a window layer, and an Ohmic contact layer that are sequentially stacked from bottom up in that order;
forming a curved diffusion region in the window layer and the Ohmic contact layer via a diffusion process;
forming a mesa structure by etching an outer periphery of the epitaxial multi-layer structure on the substrate;
forming a light input window on a bottom side of the substrate that is adapted for inletting light;
forming a p-type electrode on the Ohmic contact layer, and an n-type electrode on the bottom side of the substrate, wherein the inversion layer provides supplementary regulation of an electric field distribution that is regulated by the field control charge layer.

2. The method of making the single-photon detector as claimed in claim 1, wherein the inversion layer is made of one of InP, InGaAs, InAlAs, InAlGaAs, and InGaAsP, or any combination or combinations of the above.

3. The method of making the single-photon detector as claimed in claim 1, wherein the inversion layer has an integral charge density that ranges from 2.0×e¹²/cm² to 4.0×e¹²/cm².

4. The method of making the single-photon detector as claimed in claim 1, wherein the field control charge layer has a thickness that ranges from 150 nm to 300 nm, the multiplication layer has a thickness that ranges from 400 nm to 800 nm, and the inversion layer has a thickness that ranges from 150 nm to 300 nm.

5. The method of making the single-photo detector as claimed in claim 1, wherein the step of forming the curved diffusion region includes:
forming a preparatory etch layer on the Ohmic contact layer;
defining an etching region on the preparatory etch layer, and etching away the etching region from the preparatory etch layer to form an etched opening that corresponds to the etching region and that exposes a portion of the Ohmic contact layer; and
forming the curved diffusion region via a p-type diffusion process performed on the Ohmic contact layer and the window layer through the etched opening with a p-type dopant.

6. The method of making the single-photon detector as claimed in claim 1, wherein the step of forming the mesa structure includes:
etching an outer periphery of each of the Ohmic contact layer, the window layer, the migration layer, the inversion layer, the multiplication layer, the field control charge layer, the transition layer, the absorption layer, the buffer layer, and the substrate until the substrate is recessed to a depth lower than the top side of the substrate; and
further etching the outer periphery of each of the Ohmic contact layer, the window layer, the migration layer, and the inversion layer until a top surface of the outer periphery of the multiplication layer is exposed;
whereby the mesa structure has a first mesa on the substrate, and a second mesa on the multiplication layer.

7. The method for making the single-photon detector as claimed in claim 6, wherein, after the step of forming the mesa structure, further includes:
forming a passivation layer over the first mesa and the second mesa, said passivation layer being made from a high resistivity polymer material, or one of SiO₂, SiNₓ, and Al₂O₃, or any combination or combinations of the above.

8. The method for making the single-photon detector as claimed in claim 1, wherein the step of forming the light input window, includes:
etching the bottom side of the substrate to form a recess, a depth of the recess from the bottom side being less than an entire thickness of the substrate; and
filling the recess of the substrate with an anti-reflective coating to form the light input window.

9. A single-photon detector comprising:
a substrate;
an epitaxial multi-layer structure that includes
a buffer layer, an absorption layer, a transitional layer, a field control charge layer, a multiplication layer, an inversion layer, a migration layer, a window layer, and an Ohmic contact layer that are sequentially stacked from bottom up in that order on a top side of said substrate;
a curved diffusion region formed in said Ohmic contact layer and said window layer;
a mesa structure formed via etching on a portion of an outer periphery of said epitaxial multi-layer structure;
a light input window formed on a bottom side of said substrate adapted for inletting light;
a p-type electrode formed on said Ohmic contact layer; and
an n-type electrode formed on said bottom side of said substrate;
wherein said inversion layer provides supplementary regulation of an electric field distribution that is regulated by said field control charge layer.

10. The single-photon detector as claimed in claim 9, wherein said mesa structure includes:
a first mesa that has a first mesa top defined by a top surface of said multiplication layer, and a first mesa sidewall extending downward to a peripheral surface of said substrate lower than said top side of said substrate, said first mesa including said multiplication layer, said field control charge layer, said transition layer, said absorption layer, said buffer layer, and a portion of said substrate;
a second mesa that has a second mesa top defined by a top surface of said Ohmic contact layer, and a second mesa sidewall that extends downward to said first mesa top, said second mesa including said Ohmic contact layer, said window layer, said migration layer, and said inversion layer.

11. The single-photon detector as claimed in claim 10, further comprising a passivation layer that is formed over said first mesa and said second mesa, and that is made of a high resistivity polymer material or one of SiO₂, SiNₓ, Al₂O₃, or any combination or combinations of the above.

12. The single-photon detector as claimed in claim 9, wherein said inversion layer is made of one of InP, InGaAs, InAlAs, InAlGaAs, and InGaAsP, or any combination or combinations of the above.

13. The single-photon detector as claimed in claim 9, wherein said inversion layer has an integral charge density that ranges from 2.0×e¹²/cm² to 4.0×e¹²/cm².

14. The single-photon detector as claimed in claim 9, wherein said field control charge layer has a thickness that ranges from 150 nm to 300 nm, said multiplication layer has a thickness that ranges from 400 nm to 800 nm, and said inversion layer has a thickness that ranges from 150 nm to 300 nm.

15. The single-photon detector as claimed in claim 9, wherein:
said substrate has a recess indenting from said bottom side of said substrate, a depth of said recess being less than an entire thickness of said substrate, and
an anti-reflective coating is filled in said recess of said substrate to form said light input window.

16. A single-photon detector array comprising a plurality of single-photon detectors as claimed in claim 9 that are arranged in an array via a flip chip connection and integrated into an addressable circuit, said p-type electrodes of said single-photon detectors being electrically isolated from each other, and said n-type electrodes of said single-photon detectors being electrically connected to form a common electrode.
